(19) United States
(12) Patent Application Publication
(10) Pub. No.: US 2026/0022467 A1
(43) Pub. Date: Jan. 22, 2026

(54) MULTIPLE TEMPERATURE REACTOR SYSTEM AND METHOD

(71) Applicant: ASM IP Holding B.V., Almere (NL)

(72) Inventors: Paul Ma, Scottsdale, AZ (US); Todd Robert Dunn, Cave Creek, AZ (US); Eric James Shero, Phoenix, AZ (US)

(21) Appl. No.: 19/270,713

(22) Filed: Jul. 16, 2025

Related U.S. Application Data
(60) Provisional application No. 63/673,569, filed on Jul. 19, 2024.

(51) Int. Cl. C23C 16/52; C23C 16/455; C23C 16/458; C23C 16/46; C23C 16/511

(52) U.S. Cl. CPC C23C 16/52; C23C 16/45519; C23C 16/4586; C23C 16/46; C23C 16/511

(57) ABSTRACT

Reactor systems and methods for rapidly modulating a temperature of a substrate are disclosed. Exemplary reactor systems can include one more temperature regulating gas sources coupled to a reaction chamber of a reactor. Additionally or alternatively, exemplary reactor systems can include a lift pin assembly that can move a substrate away from a susceptor surface during processing.

### CROSS-REFERENCE TO RELATED APPLICATIONS

This application is a nonprovisional of, and claims priority to and the benefit of, U.S. Provisional Patent Application No. 63/673,569, filed Jul. 19, 2024 and entitled “MULTIPLE TEMPERATURE REACTOR SYSTEM AND METHOD,” which is hereby incorporated by reference herein.

### FIELD OF DISCLOSURE

The present disclosure generally relates to apparatus for gas-phase processes. More particularly, the disclosure relates to reactor systems capable of quickly altering a substrate temperature during processing and to methods of using the same.

### BACKGROUND OF THE DISCLOSURE

Gas-phase processes, such as chemical vapor deposition (CVD), plasma-enhanced CVD (PECVD), atomic layer deposition (ALD), and the like are often used to deposit materials onto a surface of a substrate, etch material from a surface of a substrate, and/or clean or treat a surface of a substrate. For example, gas-phase processes can be used to deposit or etch layers on a substrate to form semiconductor devices, flat panel display devices, photovoltaic devices, microelectromechanical systems (MEMS), and the like.

Reactors used in gas-phase processing often include a susceptor to hold a substrate in place and to heat or cool the substrate during processing. The susceptor is generally configured to heat (or cool) a substrate to a temperature within a specific range.

In some cases, it may be desirable to expose a substrate within a reactor to two or more different process steps at substantially different temperatures. For example, it may be desirable to deposit material at one temperature and anneal or densify the material at another temperature. Additionally or alternatively, it may be desirable or adsorb a precursor on a surface of a substrate at a first temperature and to react the adsorbed precursor with a reactant at a second temperature. With some reactor systems, it may take an undesirably long time to heat and/or cool the susceptor from one process temperature to another.

Accordingly, improved reactor systems, which can be used to process substrates at different temperatures and that are capable of rapidly changing substrate temperature, are desired.

Any discussion of problems and solutions in this section has been solely for the purposes of providing a context for the present disclosure; such discussion should not be taken as an admission that any or all of the discussion was known at the time the invention was made.

### SUMMARY OF THE DISCLOSURE

Various embodiments of the present disclosure provide reactor systems and methods for processing a substrate, which allow for or include a rapid change in temperature of the substrate. The reactor systems and methods described herein are suitable for use in a variety of gas-phase processes, such as chemical vapor deposition processes (including plasma-enhanced chemical vapor deposition processes), gas-phase etching processes (including plasma-enhanced gas-phase etching processes), gas-phase cleaning processes (including plasma-enhanced cleaning processes), and gas-phase treatment processes (including plasma-enhanced gas-phase treatment processes). As set forth in more detail below, exemplary reactor systems and methods are particularly well suited for processes that include multiple deposition steps and/or that desirably run at multiple temperatures within a reaction chamber.

In accordance with various embodiments of the disclosure, a reactor system includes a reactor comprising a chamber defined, in part, by a chamber wall, a susceptor configured to retain a substrate during processing, a temperature regulating gas source coupled to the reaction chamber via a conduit, the temperature regulating gas source comprising a temperature regulating gas, and a gas temperature regulating device configured to increase and/or decrease a temperature of the temperature regulating gas. In accordance with examples of these embodiments, the conduit is configured to provide the temperature regulating gas proximate the susceptor. In some cases, the temperature regulating gas can be provided above a substrate—e.g., when a substrate is within a lower chamber of the reactor or through a designated channel through a gas distribution device. In some cases, the temperature regulating gas can be provided below a substrate—e.g., the temperature regulating gas can be directed toward a backside of the susceptor. In some cases, the conduit is through the chamber wall. In some cases, the conduit comprises a portion of a gas distribution device. In some cases, the gas temperature regulating device is within the reactor, such as within a lower chamber of the reactor. In some cases, the gas temperature regulating device is exterior the reactor. The gas temperature regulating device can be or include, for example, one or more of a microwave plasma device, a radiant heater, an infrared heater, a flash lamp, a compressor, or the like.

In accordance with further exemplary embodiments of the disclosure, a deposition method includes placing a substrate on a surface of a susceptor, heating the substrate to a first temperature using a first heater, using one or more lift pins, and moving the substrate to a lifted position and heating the substrate in the lifted position to a second temperature different from the first position, wherein a temperature of the substrate is modulated during the deposition method. In accordance with examples of these embodiments, the first temperature is greater than the second temperature. In other cases, the second temperature is greater than the first temperature. In some cases, the substrate can be moved during a deposition cycle—e.g., the method can include exposing the substrate to a reactant while the substrate is on the surface of the susceptor and/or exposing the substrate to a precursor while the substrate is in the lifted position. In some cases, material can be deposited at a first temperature, and the deposited material can be treated (e.g., annealed or densified) at a second temperature. In such cases, the deposition and treatment steps can be repeated. In some cases, the method steps can be repeated to fill a feature, such as a gap, on a surface of the substrate.

In accordance with yet additional exemplary embodiments of the disclosure, a method of modulating a temperature of a substrate within a reactor includes placing a substrate on a surface of a susceptor, using a first heater, heating the substrate in a first position to a first temperature, and using an inert gas plasma source, heating the substrate in a second position to a second temperature. In some cases, the first position and the second position are within different reaction chambers of a module. In other cases, the first position and the second position are within the same reaction chamber. In accordance with examples of the disclosure, the substrate is grounded in the first position and in the second position. In such cases, the susceptor can be coupled to a first ground plane in the first position and a ground plane that supports a substrate provides a second ground plane in the second position. The inert gas plasma source can be or include a microwave plasma source and/or an RF plasma source. In some cases, the method includes performing an anneal process when the substrate is in the second position.

In accordance with yet additional exemplary embodiments of the disclosure, a reactor system includes a reactor comprising an upper chamber region and a lower chamber region, a susceptor configured to retain a substrate during processing, the susceptor comprising a top surface defining, in part, the upper chamber region (e.g., when the susceptor is in a processing position), and a heater disposed in the lower chamber region and separate from the susceptor. The reactor system can additionally include a gas curtain between the upper chamber region and the lower chamber region or a portion thereof. Additionally or alternatively, the reactor system can include a shutter between the upper chamber region and the lower chamber region or a portion thereof.

Both the foregoing summary and the following detailed description are exemplary and explanatory only and are not restrictive of the disclosure or the claimed invention.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a reactor system in accordance with various embodiments of the disclosure.

FIGS. 2 and 3 illustrate another reactor system in accordance with exemplary embodiments of the disclosure.

FIGS. 4 and 5 illustrate another reactor system in accordance with exemplary embodiments of the disclosure.

FIG. 6 illustrates yet another reactor system in accordance with further exemplary embodiments of the disclosure.

FIG. 7 illustrates another reactor system in accordance with further exemplary embodiments of the disclosure.

FIG. 8 illustrates yet another reactor system in accordance with further exemplary embodiments of the disclosure.

FIG. 9 illustrates an exemplary process system in accordance with various embodiments of the disclosure.

FIG. 10 illustrates an exemplary process module of a process system in accordance with various embodiments of the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS OF THE DISCLOSURE

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

As set forth in more detail below, various embodiments of the disclosure relate to reactor systems, components thereof, and to methods of using the reactor systems and components that allow for rapid heating and/or cooling of a substrate, which allows for processing (e.g., depositing material on the substrate, cleaning a surface of the substrate, heating or annealing material on a substrate surface, treating a surface of the substrate, or the like) with temperature differences of greater than 5° C. or 100° C. or between about 25° C. and about 150° C. within, for example, in less than 10 or about 30 seconds or between about 1 and about 10 seconds or between about 1 and about 30 seconds.

As used herein, the term substrate may refer to any underlying material or materials, including and/or upon which one or more layers can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can additionally or alternatively include various features, such as recesses, lines, and the like formed within or on at least a portion of a layer of the substrate.

In some embodiments, the term film refers to a layer extending in a direction perpendicular to a thickness direction. In some embodiments, layer refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, the term gas may refer to material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution device, such as a showerhead, other gas distribution device, or the like, may be used for, e.g., sealing the reaction space, and may include a seal gas, such as a rare gas.

In some cases, such as in the context of deposition of material, the term precursor can refer to a compound that participates in the chemical reaction that produces another compound, and particularly to a compound that constitutes a film matrix or a main skeleton of a film, whereas the term reactant can refer to a compound, in some cases other than precursors, that activates a precursor, modifies a precursor, or catalyzes a reaction of a precursor. In some cases, the terms precursor and reactant can be used interchangeably. The term inert gas refers to a gas that does not take part in a chemical reaction to an appreciable extent and/or a gas that excites a precursor when, for example, RF or microwave power is applied, but unlike a reactant, it may not become a part of a film matrix to an appreciable extent.

The term cyclic deposition process or cyclical deposition process may refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. In some cases, an inert gas and/or one or more reactants can continuously flow during multiple cycles of a cyclical process and a precursor and/or plasma can be pulsed.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, etc. in some embodiments. For example, the term about can refer to +/−20, 10, 5, 2, or 1 percent of a value. Further, in this disclosure, the terms including, constituted by and having can refer independently to typically or broadly comprising, comprising, consisting essentially of, or consisting of in some embodiments. In accordance with aspects of the disclosure, any defined meanings of terms do not necessarily exclude ordinary and customary meanings of the terms.

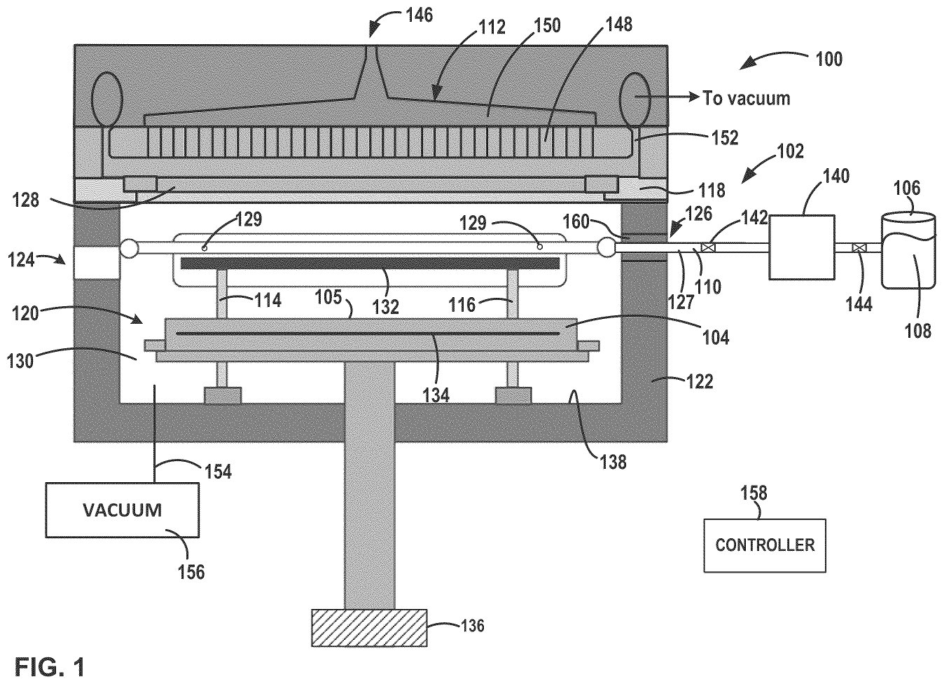

Turning now to the figures, FIG. 1 illustrates a reactor system (sometimes referred to herein as a process system) 100 in accordance with embodiments of the disclosure. Reactor system 100 includes a reactor 102, a susceptor 104, a temperature regulating gas source 106, a temperature regulating gas 108 within temperature regulating gas source 106, and a conduit 110. In the illustrated example, reactor system 100 also includes a gas distribution device 112, lift pins 114, 116, a flow control ring 118, vacuum source 156, and controller 158. Although not illustrated, reactor system 100 may additionally include direct and/or remote plasma and/or thermal excitation apparatus for one or more reactants and/or within reactor 102.

Reactor 102 can be or include a reaction chamber suitable for gas-phase reactions. Reactor 102 can be formed of suitable material, such as quartz, metal, or the like, and can be configured to retain one or more substrates for processing. Reactor system 100 can include any suitable number of reactors 102 and can optionally include one or more substrate handling systems.

Reactor 102 can be used to deposit material onto a surface of a substrate 132, etch material from a surface of substrate 132, clean a surface of substrate 132, treat a surface of substrate 132, deposit material onto a surface within reactor 102, clean a surface within reactor 102, etch a surface within reactor 102, and/or treat a surface within reactor 102. Reactor 102 can be a standalone reactor or part of a cluster tool. Further, reactor 102 can be dedicated to deposition, etch, clean, or treatment processes, or reactor 102 may be used for multiple processes—e.g., for any combination of deposition, etch, clean, and treatment processes.

Reactor 102 can be configured as a CVD reactor, a cyclical deposition process reactor (e.g., a cyclical CVD reactor), an ALD reactor, or the like, any of which may include plasma apparatus, such as direct and/or remote plasma apparatus. Reactor 102 can be configured to deposit a variety of films or layers, such as multi-component layers, epitaxial layers, or the like, and/or can be configured to perform an etch and/or clean process.

As Illustrated, reactor 102 includes a chamber 120 defined, in part, by a chamber wall 122. Chamber wall 122 can include a gate valve opening 124 and a conduit opening 126. Chamber 120 can be divided into an upper chamber region or processing region 128 and a lower chamber region or load/unload region 130. During processing, substrate 132 can be at a first temperature when a top surface of substrate 132 is within or partially defines upper chamber region 128 (first position) and can be at a second temperature when substrate 132 is within lower chamber region 130 (second position). In some cases, the lower chamber region is below a top surface 105 of susceptor 104 when susceptor 104 is in a processing position. In some cases, the second position can be below gate valve opening 124.

Susceptor 104 is configured to retain substrate 132 in place during processing. One or more sections of susceptor 104 can be heated, cooled, or be at ambient process temperature during processing. In accordance with examples of the disclosure, susceptor 104 includes a temperature regulating device 134, such as a heater (e.g., a resistive heater) and/or a cooling device (e.g., a conduit for a cooling medium, such as chilled water).

In the illustrated example, reactor system 100 includes a mechanism 136 to move susceptor 104 from lower chamber region 130 to upper chamber region 128. Mechanism 136 can include any suitable apparatus capable of moving susceptor 104 relative to a bottom chamber wall 138. By way of example, mechanism 136 includes a servo motor to drive susceptor 104 along a vertical axis. Mechanism 136 can suitably reside outside reaction chamber 102.

Susceptor 104 can be formed of any suitable material, such as ceramic material, such as boron nitride, aluminum nitride, quartz, and ceramic-coated materials, such as ceramic-coated metals. Susceptor 104 can also include resistive heating material. Exemplary materials suitable for resistive heating material include tungsten (W), nichrome (NiCr), cupronickel (CuNi), graphite, molybdenum disilicide (MoSi₂) or any other suitable heater material. The resistive heating material can be coated onto (e.g., patterned onto), for example, ceramic or ceramic-coated metal. Susceptor 104 can include an additional protective layer formed overlying the resistive heating material. The protective layer can be formed of, for example, ceramic material.

Temperature regulating gas source 106 is coupled to chamber 120 (e.g., lower chamber region 130) via conduit 110. Temperature regulating gas source 106 includes temperature regulating gas 108. Temperature regulating gas 108 can be or include a relatively high thermal conductivity gas, such as a gas having a thermal conductivity greater than the thermal conductivity of hydrogen or helium at an operating pressure and a temperature, or greater than about 125 mW/m·K (milliwatts per meter kelvin) at 100 kPA or the saturation pressure if such is less than 100 kPA at 300 K. For example, temperature regulating gas 108 can be or include one or more of hydrogen, helium, or any mixture thereof, and may additionally include argon. Although illustrated as a single gas source, temperature regulating gas source 106 can include two or more gas sources, wherein the respective temperature regulating gases are separately provided to chamber 120 or are mixed prior to or within chamber 120.

Temperature regulating gas source 106 is fluidly coupled to a gas temperature regulating device 140 that is configured to increase and/or decrease a temperature of the temperature regulating gas 108. Temperature regulating device 140 can be, as illustrated, exterior of chamber 120. Additionally or alternatively, temperature regulating device 140 can be within chamber 120 (e.g., within lower chamber region 130), as described in more detail below in connection with other illustrated examples of reactor systems. Temperature regulating device 140 can be or include, for example, a heat exchanger, a resistive heater, a chiller, a microwave plasma device, a radiant heater, an infrared heater, a flash lamp, a compressor, or the like.

As illustrated, temperature regulating gas 108 is provided to chamber 120 via conduit 110, which can include one or more valves 142, 144. Valve 142, 144 can be on/off and/or control valves. In accordance with examples of the disclosure, at least one of valve 142, 144 is a control valve coupled to a controller, such as controller 158 described below, such that a flow rate of temperature regulating gas 108 is controlled during processing of substrate 132. Conduit 110 and reactor system 100 can be further configured to provide temperature regulating gas 108 proximate the substrate 132—e.g., within lower chamber region 130. In the example illustrated in FIG. 1, temperature regulating gas 108 is not provided through gas distribution device 112. In other examples described below, temperature regulating gas 108 is additionally or alternatively introduced through gas distribution device 112. In the example illustrated in FIG. 1, conduit 110 includes a section 127 through chamber wall 122 and into lower chamber region 130. Conduit 110 can also include a section 127 that extends within (e.g., substantially spans a cross-sectional dimension of) lower chamber region 130. Conduit 110 can be formed of any suitable material, such as stainless steel tubing or the like. An insulator 160 can be about at least a portion of conduit 110. Further, conduit 110 can include one or more holes 129 to facilitate providing temperature regulating gas 108 to a surface of a substrate. By providing temperature regulating gas 108 through chamber wall 122, a temperature of fewer components, such as gas distribution device 112 and the like, are affected.

Gas distribution device 112 is configured to receive and facilitate distribution of one or more gases to reactor 102, and particularly to upper chamber region 128 during substrate processing. Gas distribution device 112 can include an inlet 146 and a plurality of holes 148 coupled to a plenum 150.

Reactor system 100 can also include an exhaust path 152 and/or 154 to a vacuum source 156. Vacuum source 156 can include one or more vacuum sources. Exemplary vacuum sources include one or more dry vacuum pumps and/or one or more turbomolecular pumps.

Controller 158 can be configured to perform various functions and/or steps as described herein. Controller 158 can include one or more microprocessors, memory elements, and/or switching elements to perform the various functions. Although illustrated as a single unit, controller 158 can alternatively comprise multiple devices. By way of examples, controller 158 can be used to control gas flow of temperature regulating gas 108—e.g., via one or more of valves 142, 144 and to move susceptor between a first position, in which the substrate is within upper chamber region 128 and in contact with a surface of susceptor 104, to a second position, in which the substrate is within lower chamber region 130 and elevated with respect to (e.g., not in contact with) the surface of susceptor 104.

A method of operating reactor system 100 can include, for example, placing a substrate on a surface of a susceptor, heating or cooling the substrate to a first temperature using a first heater or cooler (e.g., temperature regulating device 134), using one or more lift pins, moving the substrate to a lifted position and heating the substrate in the lifted position to a second temperature different from the first position, wherein a temperature of the substrate is modulated within lower chamber region 130.

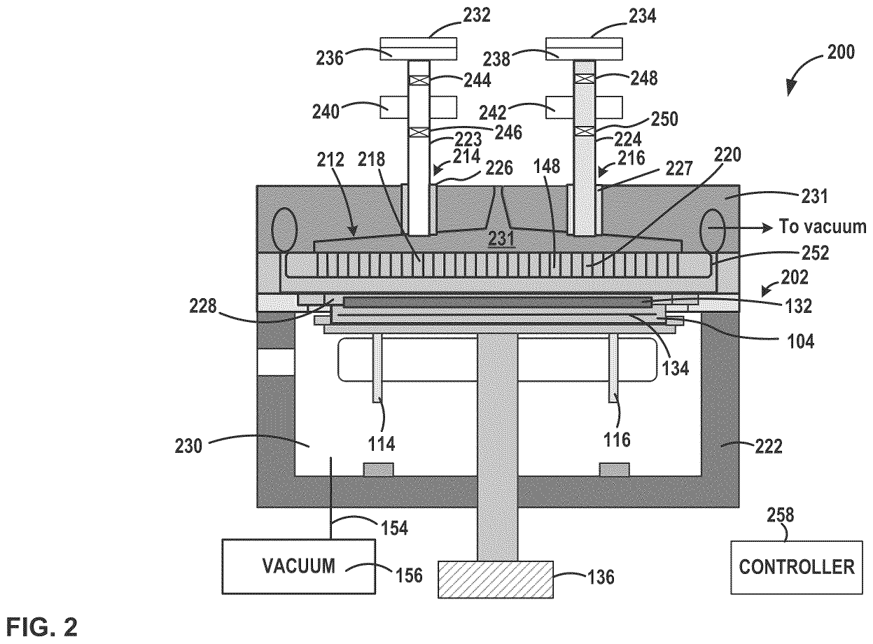

FIG. 2 illustrates another reactor system 200 in accordance with additional examples of the disclosure. Reactor system 200 is similar to reactor system 100, except reactor system 200 includes a reactor 202 that includes a reactor wall 222, a gas distribution device 212, one or more temperature regulating gas sources 232, 234 that are fluidly coupled to an upper chamber region 228 and may be isolated from lower a chamber region 230, such that most temperature regulating gas 236, 238 from one or more temperature regulating gas sources 232, 234 is exhausted through an exhaust path 252 within an upper or a top plate 233. Temperature regulating gas 236, 238 can be the same or similar to temperature regulating gas 108 described above. Temperature regulating gas 236 and 238 include the same or different gases. Temperature regulating gas 236 and 238 are suitably controlled at different temperatures.

Reactor system 200 can also include gas temperature regulating devices 240, 242, which can be the same or similar to gas temperature regulating device 140. Similarly, reactor system 200 can include valves 244-250, which can be the same or similar to valves 142, 144.

In accordance with examples of the disclosure, temperature regulating gas sources 232 can provide a relatively cool gas to upper chamber region 128 and temperature regulating gas sources 234 can provide a relatively hot gas to upper chamber region 128. By way of examples, gas temperature regulating devices 240 can cool temperature regulating gas 236 to a temperature of about 10° C. to about 20° C. or about 15° C. to 20° C. and/or temperature regulating devices 240 can heat temperature regulating gas 238 to a temperature of about 100° C. to about 500° C. or about 100° C. to about 400° C. or to about 300° C. to about 500° C.

Reactor system 200 can also include a controller 258, which can be similar to controller 158 described above. In accordance with examples of the disclosure, controller 258 is configured to flow both temperature regulating gas 236 and temperature regulating gas 238 and adjust a flowrate of one or both of temperature regulating gas 236 and temperature regulating gas 238. For example, controller 258 and/or reactor system 200 can be configured to provide (e.g., pulse) a precursor through gas distribution device 212 for a period of time and to increase or decrease a flow of temperature regulating gas 236 while increasing or decreasing a temperature regulating gas 238. By maintaining some flow of temperature regulating gas 236 and temperature regulating gas 238 to gas distribution device 212 (e.g., during pulsing or a precursor and/or between precursor pulses), relatively fast substrate temperature changes can be achieved.

A flowrate of temperature regulating gas 236 can be between about 1 and about 1000 SLM or between about 50 and about 500 SLM or between about 1 and about 50 SLM. Similarly, a flowrate of temperature regulating gas 238 can be between about 1 and about 1000 SLM or between about 50 and about 500 SLM or between about 1 and about 50 SLM.

Reactor 202 and reactor wall 222 can be similar to reactor 102 and chamber wall 122, except reactor wall 222 may not include a conduit therethrough to provide a temperature regulating gas to lower chamber region 130. However, in some cases, features of reactor system 100 and reactor system 200 can be combined.

Gas distribution device 212 can be similar to gas distribution device 112, except gas distribution device 212 can include one or more inlets 214, 216 to receive temperature regulating gas from one or more temperature regulating gas sources 232, 234. In some cases, one or more temperature regulating gas 236, 238 can be provided through gas distribution device 212 via dedicated holes 218, 220 and/or holes 148 used to distribute process gases.

One or more conduits 223, 224 are fluidly coupled to inlets 214, 216 of top plate 233 and may be fluidly coupled to plenum 231 of gas distribution device 212. As illustrated, insulating material 226, 227 can surround at least a portion of conduits 223, 224 to provide insulation from, for example, top plate 233, gas distribution device 212, and/or ambient conditions.

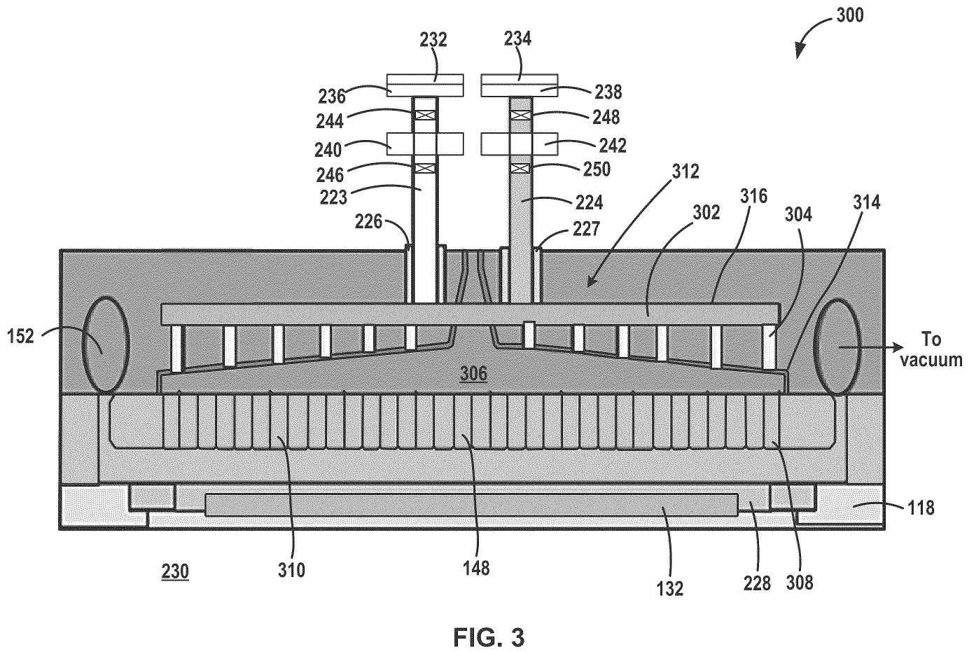

FIG. 3 illustrates a portion of a reactor system 300 in accordance with yet additional embodiments of the disclosure. Reactor system 300 can be the same as reactor system 200, except reactor system 300 includes a gas distribution device 312, which includes an additional plenum 302 to receive and distribute temperature regulating gas 236 and/or temperature regulating gas 238 through holes 304 within gas distribution device 312. In some cases, temperature regulating gas 236 and/or temperature regulating gas 238 flows from plenum 302 toward substrate 132 via dedicated holes 308, 310. Holes 308, 310 can be coupled to only one temperature regulating gas source 232 or temperature regulating gas source 234 or can be coupled to both. In some cases, one of temperature regulating gas 236 and temperature regulating gas 238 is provided via plenum 306 and the other of temperature regulating gas 236 and temperature regulating gas 238 is provided via plenum 302. which can be thermally insulated from each other—e.g., via insulating material 314 or 316.

In accordance with examples of the disclosure, holes 308, 310 can have a large cross section and may be fewer in number compared to holes 148 used to distribute a precursor and/or a reactant. For example, a cross-sectional dimension of holes 308 or 310 can be 2, 4, 5, or 10 or more times greater than a cross-sectional dimension of holes 148.

Additionally or alternatively, temperature regulating gas 236 and/or temperature regulating gas 238 can be provided to substrate 132 via holes 148, which are fluidly coupled to plenum 306, and which can provide a precursor and/or reactant to substrate 132.

A method of using reactor system 200 or 300 can include placing a substrate on a surface of susceptor 104, heating the substrate to a first temperature using a first flow ratio of temperature regulating gas 236 and temperature regulating gas 238, and heating the substrate to a second temperature using a second flow ratio of temperature regulating gas 236 and temperature regulating gas 238, wherein the first flow ratio and the second flow ratio are different. The method can additionally include steps described above in connection with reactor system 100 and/or other reactor systems described herein. As noted above, in some cases, flow rates of temperature regulating gas 236 and temperature regulating gas 238 can be continuous through one or more process steps, such as intra-cycle deposition steps and/or deposition and anneal and/or treatment steps.

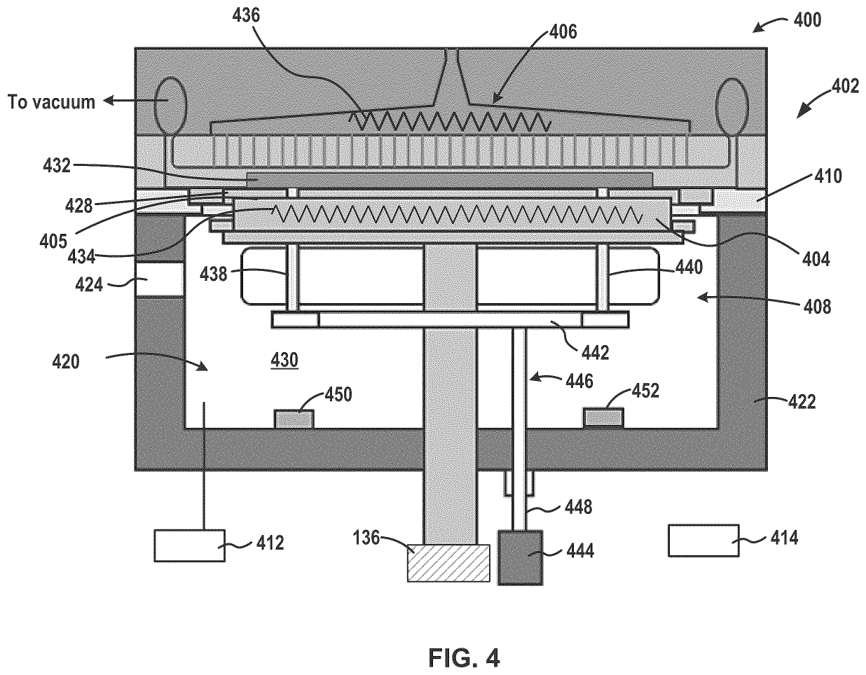

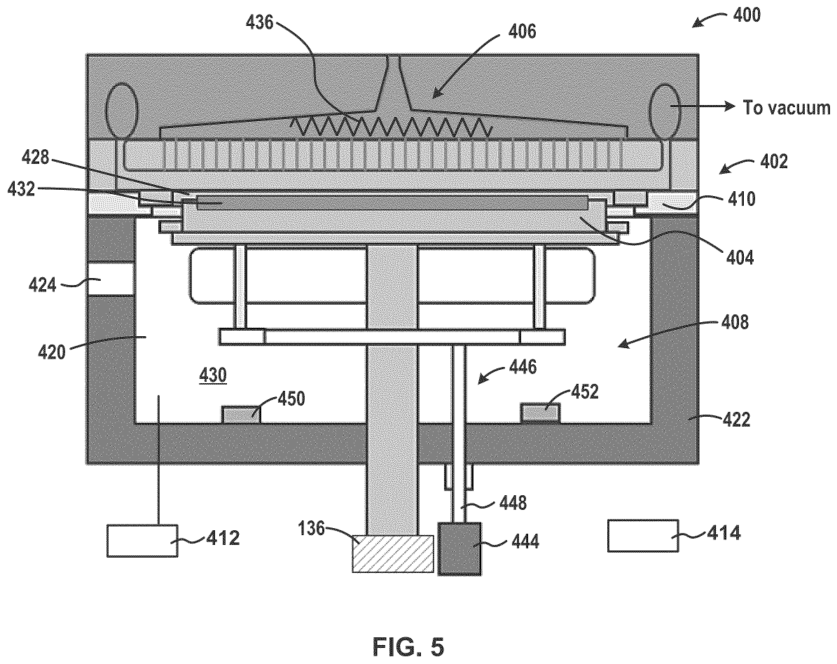

FIGS. 4 and 5 illustrate another reactor system 400 and method in accordance with examples of the disclosure. Reactor system 400 is similar to reactor systems 100-300, except reactor system 400 uses movement of a substrate to regulate a temperature of the substrate. Such substrate movement can be combined with the reactor systems and methods described above in connection with FIGS. 1-3 and/or other reactor systems and/or methods described herein.

Reactor system 400 includes a reactor 402, a susceptor 404, a gas distribution device 406, and a lift pin assembly 408. Reactor system 400 can also include a flow control ring 410, vacuum source 412, and a controller 414. Reactor system 400 may additionally include direct and/or remote plasma and/or thermal excitation apparatus for one or more reactants and/or within reactor 402.

Reactor 402 can be similar to reactor 102 and can be formed of the same or similar materials. Reactor 402 includes a chamber 420 defined, in part, by a chamber wall 422. Chamber wall 422 can include a gate valve opening 424. Chamber 420 can be divided into an upper chamber region or processing region 428 and a lower chamber region or load/unload region 430. In some cases, lower chamber region 430 is below a top surface 405 of susceptor 404 when susceptor 404 is in a processing position.

Susceptor 404 can be the same or similar to susceptor 104. As above, susceptor 404 can include a temperature regulating device 434, which can be the same or similar to temperature regulating device 134.

Gas distribution device 406 can be the same or similar to gas distribution device 112. In accordance with examples of the disclosure, gas distribution device 406 can include a temperature regulating device 436 to independently regulate a temperature of gas distribution device 406. Temperature regulating device 436 can be or include any temperature regulating device described herein.

Lift pin assembly 408 includes lift pins 438, 440, lift pin plate 442, lift pin actuator 446, including lift pin motor 444 and actuator arm 448. Although illustrated with two lift pins, lift pin assembly 408 can include any suitable number of lift pins and typically includes three lift pins. Vacuum source 412 can be the same or similar to vacuum source 156 described above.

Controller 414 can be configured to perform various functions and/or steps as described herein. Controller 414 can include one or more microprocessors, memory elements, and/or switching elements to perform the various functions. Although illustrated as a single unit, controller 414 can alternatively comprise multiple devices. By way of examples, controller 414 can be used to control gas flow or precursor(s) and/or reactant(s) to upper chamber region 428 and to move lift pins 438, 440 during processing, such that lift pins 438, 440 raise substrate 432 during a portion of a process and lower substrate 432 (e.g., rest of susceptor surface) during another portion of a process.

During operation of reactor system 400, substrate 432 can be at a first temperature when substrate 432 is within upper chamber region 428 and elevated with respect to susceptor 404 (FIG. 4), and substrate 432 can be at a second temperature when substrate 432 is within upper chamber region 428 and resting on or in contact with susceptor 404 (FIG. 5).

By way of particular example, a deposition method can include placing substrate on a surface 405 of susceptor 404, heating substrate 432 to a first temperature using a first heater (e.g., temperature regulating device 434), using one or more lift pins of lift pin assembly 408, moving the substrate to a lifted position and heating the substrate in the lifted position to a second temperature different from the first position, wherein a temperature of the substrate is modulated during the deposition method. The first temperature can be greater than the second temperature. By way of example, the second temperature can be about 50° C., 100° C. or 150° C. greater than the first temperature or be between about 100° C. and about 500° C. or be between about 200° C. and about 400° C. greater than the first temperature. Alternatively, the first temperature can be about 50° C., 100° C. or 150° C. greater than the second temperature or be between about 100° C. and about 500° C. or be between about 200° C. and about 400° C. greater than the second temperature. By way of further examples, the first temperature can be between about 300° C. and about 500° C. or between about 350° C. and about 450° C. and the second temperature can be between about 50° C. and about 150° C. or between about 50° C. and 100° C. or vice versa.

In the case of a cyclical (e.g., deposition) process, the substrate can be in a first position (e.g., resting on susceptor 404) during a step of exposing the substrate to a reactant. The cyclical process can additionally include exposing the substrate to a precursor while the substrate is in a second (lifted) position. Such a method may be particularly well suited for deposition processes that include reacting metalorganic or organometallic with a reactant in alternating cycles or in which the reactant is continually provided to the reaction chamber.

Exemplary metalorganic precursors include molecules comprising a metal atom and an organic ligand bonded to the metal though a nitrogen, oxygen, sulfur, or phosphorus atom. Exemplary organic ligands for a metalorganic precursor include dialkylamido ligands, alkylimido ligands, N,N′-dialkylamidinate ligands, N,N′-dialkyldiazadienyl ligands, alkoxide ligands, beta-diketonate ligands, alkylthiolate ligands, and alkyl- or aryl-substituted phosphine ligands. Exemplary metal atoms in a metalorganic precursor include Sc, Y, La, Ti, Zr, Hf, V, Nb, Ta, Cr, Mo, W, Ru, Co, Ni, Cu, Zn, Al, Ga, In, Si, Ge, Sn, Sb, Bi and Te. Non-limiting examples of specific precursors include titanium (IV) isopropoxide, tetrakis(ethylmethylamido) hafnium, tris(N,N-diisopropylformamidinato) lanthanum, bis(dimethylamido)bis(tert-butylimido) molybdenum, pentakis (dimethylamido) tantalum, tris(diethylamido) (tert-butylimido) niobium, bis[1-(dimethylamino)-2-propanolato]copper, bis(N,N′-di-tert-butyldiazadienyl) cobalt, and bis(N,N′-diisopropylacetamidinato) nickel.

Exemplary organometallic precursors include molecules comprising a metal atom and an organic ligand bonded to the metal through a carbon atom. Exemplary organic ligands for an organometallic precursor include cyclopentadienyl ligands, alkylcyclopentadienyl ligands, alkyl ligands, carbonyl ligands, alkene and alkenyl ligands, alkyne and alkynyl ligands, arene and aryl ligands, and allyl ligands. Exemplary metal atoms in an organometallic precursor include Sc, Y, La, Ti, Zr, Hf, V, Nb, Ta, Cr, Mo, W, Ru, Co, Ni, Cu, Zn, Al, Ga, In, Si, Ge, Sn, Sb, Bi and Te. Non-limiting examples of specific precursors include trimethylaluminum, diethylzinc, tris(methylcyclopentadienyl) yttrium, molybdenum hexacarbonyl, (3,3-dimethyl-1-butyne)dicobalt hexacarbonyl, cyclohexadiene (tricarbonyl) ruthenium, tricthylgallium, trimethylindium, bis(ethylbenzene) molybdenum, tris(dimethylamido)cyclopentadienylhafnium, bis(methylcyclopentadicnyl)methyl(methoxy) zirconium, and (allyl)tricarbonylcobalt.

Exemplary reactants include one or more oxidizing agents, nitriding agents, sulfiding agents, phosphating agents, carbonizing agents, and/or reducing agents.

Exemplary oxidizing agents include one or more of O₂, water (H₂O), hydrogen peroxide (H₂O₂), ozone (O₃), oxides of nitrogen, such as, for example, nitrogen monoxide (NO), nitrous oxide (N₂O), and nitrogen dioxide (NO₂).

Exemplary nitriding agents can be selected from one or more of nitrogen (N₂), ammonia (NH₃), hydrazine (N₂H₄) or a hydrazine derivate, a mixture of hydrogen and nitrogen, nitrogen ions, nitrogen radicals, and excited nitrogen species, and other nitrogen and hydrogen-containing gases. The nitrogen reactant can include or consist of nitrogen and hydrogen. In some cases, the nitrogen reactant does not include diatomic nitrogen.

Exemplary sulfiding agents include hydrogen sulfide (H₂S), sulfur (e.g., S₈), thiols (e.g., alkyl and aryl thiols), compounds including disulfide bonds, compounds including a sulfur-alkyl group bond, and compounds represented by the formula R—S—S—R′ or S—R, wherein R and R′ are independently selected from aliphatic (e.g., C1-C8) and aromatic groups, sulfur halides (e.g., including one sulfur, such as SCl₂ or SBr₂, or one halide, such as disulfur dichloride). The alkyl thiols can include C1-C8 alkyl thiols.

Exemplary phosphidizing agents include phosphine (PH3), phosphorus halides and oxyhalides, e.g., phosphorus trichloride (PCl3), phosphorus pentachloride (PCl5), phosphorus tribromide (PBr3), phosphorus pentabromide (PBr5), phosphorus oxychloride (POCI3), phosphorus oxybromide (POBr3)), organophosphates and organophosphites, e.g., trimethylphosphate (PO[OMe3]), trimethylphosphite (P[OMe3]), aminophosphines, e.g., tris(dimethylamino)phosphine (P[NMe2]3), alkylphosphines, e.g., tert-butyl phosphine (C4H9PH2), tricthylphosphine (P[CH2CH3]3), and silylphosphines, e.g., tris(trimethylsilyl)phosphine (P[SiMe3]3) and tri(silyl)phosphine (P[SiH3]3).

Exemplary carbonizing agents include acetylene, ethylene, alkyl halide compounds, alkene halide compounds, metal alkyl compounds, and the like. Exemplary alkyl halide compounds include CX₄, CHX₃, CH₂X₂, CH₃X, where X=F, Cl, Br, or I. Exemplary alkene halide compounds include C₂H₃X, C₂H₂X₂, C₂HX₃, and C₂X₄, where X=F, Cl, Br, or I. Exemplary alkyne halide compounds include C₂X₂ and HC₂X, where X=F, Cl, Br, or I. Exemplary metal alkyl compounds include AlMe₃, AlEt₃, Al(iPr)₃, Al(iBu)₃, Al(tBu)₃, GaMc₃, GaEt₃, Ga(iPr)₃, Ga(iBu)₃, Ga(tBu)₃, InMe₃, InEt₃, In(iPr)₃, In(iBu)₃, In(tBu)₃, ZnMc₂, and ZnEt₂.

Exemplary reducing agents include one or more of forming gas (H₂+N₂), ammonia (NH₃), hydrazine (N₂H₄), an alkyl-hydrazine (e.g., tertiary butyl hydrazine (C₄H₁₂N₂)), molecular hydrogen (H₂), hydrogen atoms (H), a hydrogen plasma, hydrogen radicals, hydrogen excited species, (e.g., C1-C4) alcohols, (e.g., C1-C4) aldehydes, (e.g., C1-C4) carboxylic acids, (e.g., B1-B12) boranes, or an amine.

At an end of a process, susceptor 404 and lift pin assembly 408 can be lowered, such that substrate 432 is within lower chamber region 430 and can be removed through gate valve opening 424. In some cases, lift pins 438, 440 can rest on lift pin pads 450, 452 or lift pin plate 442, such that lift pins 438, 440 raise substrate 432, relative to susceptor surface 405.

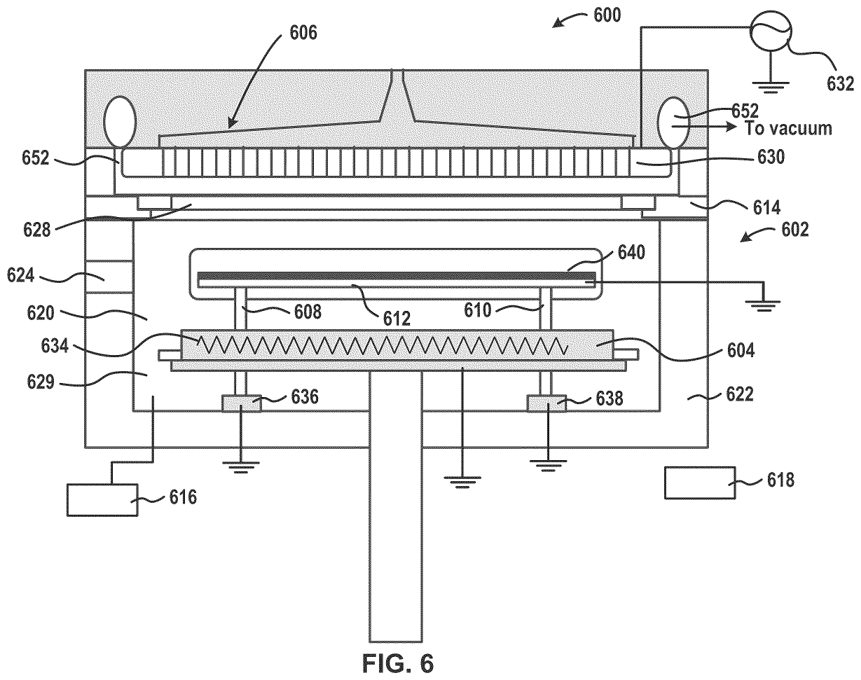

FIG. 6 illustrates another reactor system 600 and method in accordance with examples of the disclosure. Reactor system 600 includes a reactor 602, a susceptor 604, a gas distribution device 606, lift pins 608, 610, and a moveable ground plane 612. Reactor system 600 can also include a flow control ring 614, a vacuum source 616, and a controller 618. Reactor system 600 may additionally include remote plasma and/or thermal excitation apparatus for one or more reactants and/or within reactor 602.

Reactor 602 can be similar to reactor 102 and can be formed of the same or similar materials. Reactor 602 includes a chamber 620 defined, in part, by a chamber wall 622. Chamber wall 622 can include a gate valve opening 624. Chamber 620 can be divided into an upper chamber region or processing region 628 and a lower chamber region or load/unload region 629, as described above in connection with FIG. 1.

Susceptor 604 can be the same or similar to susceptor 104. As above, susceptor 604 can include a temperature regulating device 634, which can be the same or similar to temperature regulating device 134. Further, as illustrated, susceptor 604 can be coupled to ground to form a second ground plane as described below.

Gas distribution device 606 can be the same or similar to gas distribution device 112. In accordance with examples of the disclosure, gas distribution device 606 includes a plate 630, which forms an electrode for plasma formation. As illustrated, plate 630 is electrically coupled to a plasma power source 632. In this case, a plasma produced by plate 630, susceptor 604, and power source 632 can be, for example, a capacitively-coupled RF plasma. Alternatively, an inductively coupled plasma (ICP) can be used.

Lift pins 608, 610 can be the same or similar to lift pins 114, 116 described above. In accordance with examples of the disclosure, lift pins 608, 610 can be configured to raise or lower moveable ground plane 612. In accordance with further examples, lift pins 608, 610 are conductive to facilitate grounding of moveable ground plane 612—e.g., through lift pin pads 636, 638.

Moveable ground plane 612 is configured to retain a substrate 640 in a lifted position and can retain substrate 640 during plasma heating—e.g., when substrate 640 is lifted and separated from susceptor 604. Moveable ground plane 612 can be configured in an annual shape or have a circular cross section. Moveable ground plane 612 can be formed of conductive material, such as aluminum, anodized aluminum, nickel, stainless steel, Hastelloy, or the like.

Vacuum source 616 can be the same or similar to vacuum source 156 described above. As illustrated, vacuum source 616 can be coupled to exhaust path 652 and/or lower chamber region 629.

Controller 618 can be similar to controller 158 described above, except controller 618 is configured to move moveable ground plane 612 in a process of heating substrate 640. In addition, controller 618 can be configured to provide plasma power to plate 630 to heat substrate 640 to a second temperature using a plasma process and heat substrate 640 to a first temperature using a heater (e.g., temperature regulating device 634) to a first temperature.

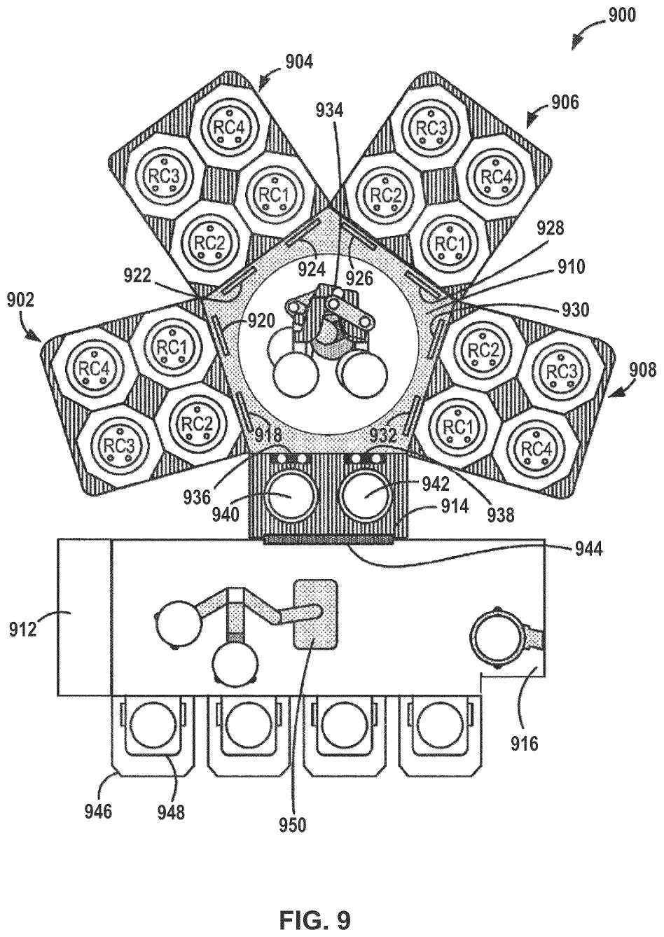

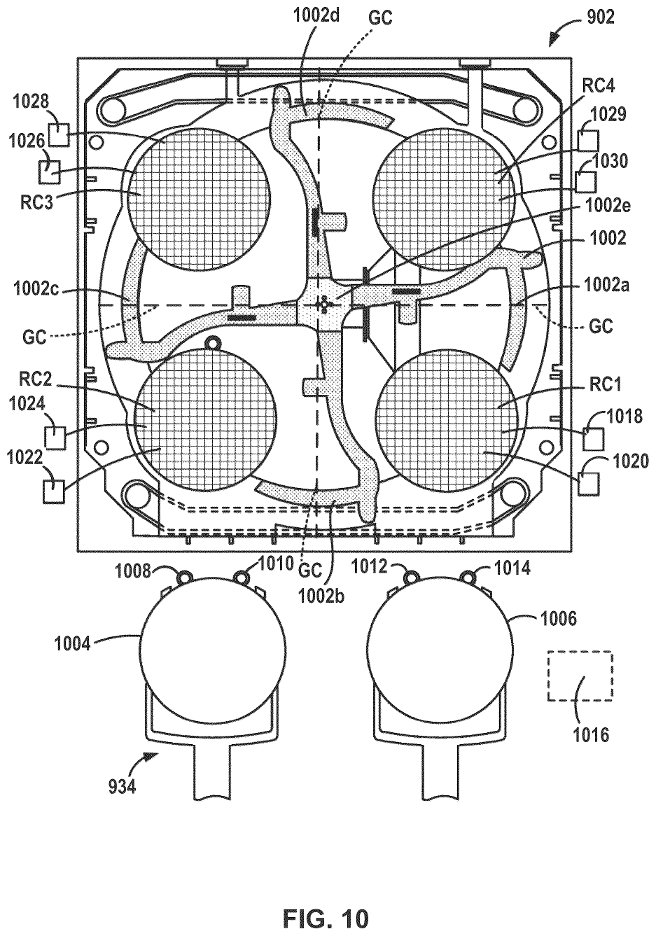

Reactor system 600 can be used to rapidly heat a surface of a substrate using a (e.g., inert gas) plasma formed within reactor 602. In accordance with examples of the disclosure, a method of modulating a temperature of a substrate within a reactor (e.g., reactor 602) includes placing a substrate on a surface of a susceptor, using a first heater (e.g., temperature regulating device 634), heating the substrate in a first position (e.g., substrate resting on the susceptor) to a first temperature, and using an inert gas plasma source (e.g., formed using plate 630 and susceptor 604 as electrodes and applying plasma power to at least one of the electrodes), heating the substrate in a second position (e.g., a raised position, such that substrate 640 is suspended by moveable ground plane 612) to a second temperature. In some cases, the first position and the second position are within different reaction chambers of a module, as discussed in more detail below in connection with FIGS. 9 and 10. In other cases, as illustrated in FIG. 6, the first position and the second position are within the same reaction chamber of a reactor system. In some cases, a plasma can be formed when the substrate is in the first and second positions.

The steps of heating to first and second temperatures can be performed in lower chamber region 629, in upper chamber region 628, or both. The steps of heating can include heating substrate 640 to a second temperature greater than the first temperature. For example, the second temperature can be about 50° C. to about 550° C. or about 300° C. to about 500° C. greater than the first temperature.

The reactor system 600 and associated methods can be used for a variety of applications. For example, the steps of heating can be used to heat substrate 640 during and/or between process steps of a cyclical deposition process and/or can be used to anneal material on a surface of a substrate before and/or after a deposition process—e.g., a deposition process performed in reactor 602.

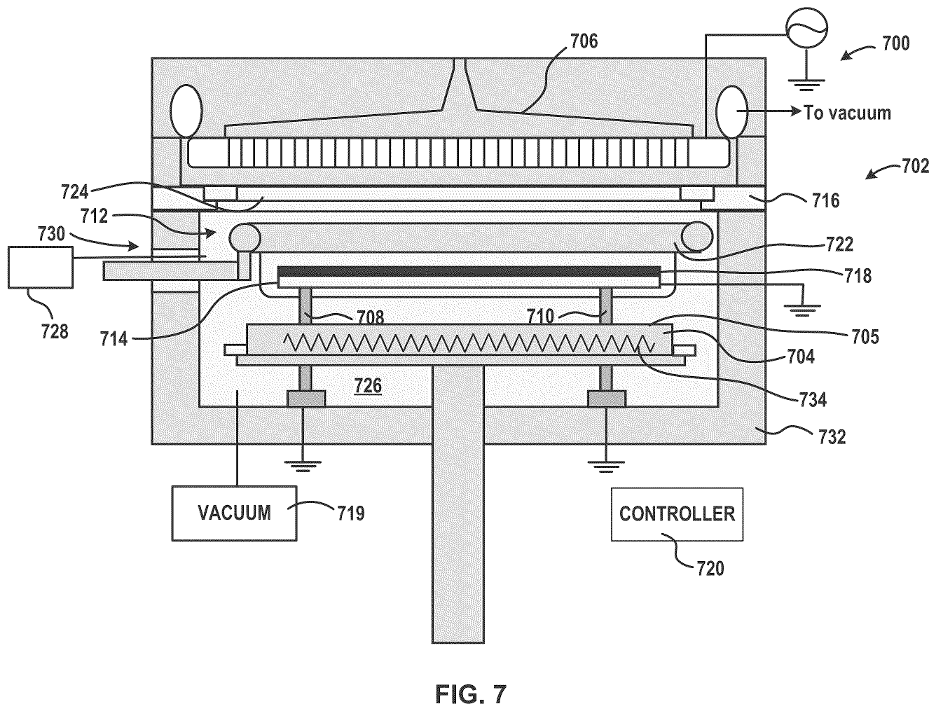

FIG. 7 illustrates another reactor system 700 in accordance with examples of the disclosure. Reactor system 700 is similar to reactor system 600, except reactor system 700 includes a microwave plasma source to heat a substrate 718. Reactor system 700 includes a reactor 702, a susceptor 704, a gas distribution device 706, lift pins 708, 710, a microwave plasma source 712 and a moveable ground plane 714. Reactor system 700 can also include a flow control ring 716, vacuum source 719, and a controller 720. Reactor system 700 may additionally include remote plasma and/or thermal excitation apparatus for one or more reactants and/or within reactor 702.

Reactor 702, a susceptor 704, a gas distribution device 706, lift pins 708, 710, and moveable ground plane 714 can be the same or similar to the respective components described above in connection with FIG. 6. Reactor 702 can include an upper chamber region 724 and a lower chamber region 726.

Microwave plasma source can include, for example, one or more pole antennas 722 and an inert gas source 728. As illustrated, one or more pole antennas 722 can be located within lower chamber region 726. Inert gas can be provided to lower chamber region 726 via gas distribution device 706 and/or via a dedicated conduit 730 that extends through a chamber wall 732 of reactor 702.

During operation of reactor system 700, a substrate is placed on a surface 705 of susceptor 704. Using a first heater 734 (e.g., on or within susceptor 704), the substrate is heated in a first position (e.g., resting on surface 705) to a first temperature, and using an inert gas (e.g., microwave) plasma source, and the substrate is heated in a second position (e.g., raised above surface 705) to a second temperature. As above, the second temperature can be about 50° C. to about 550° C. or about 300° C. to about 500° C. greater than the first temperature. Reactor system 700 may be particularly well suited for performing an anneal step (e.g., when substrate 718 is in the second/elevated position) during a deposition method or process. A method of operating reactor system 700 can additionally include degassing reactor 702—e.g., using microwaves or megasonic or ultrasonic waves.

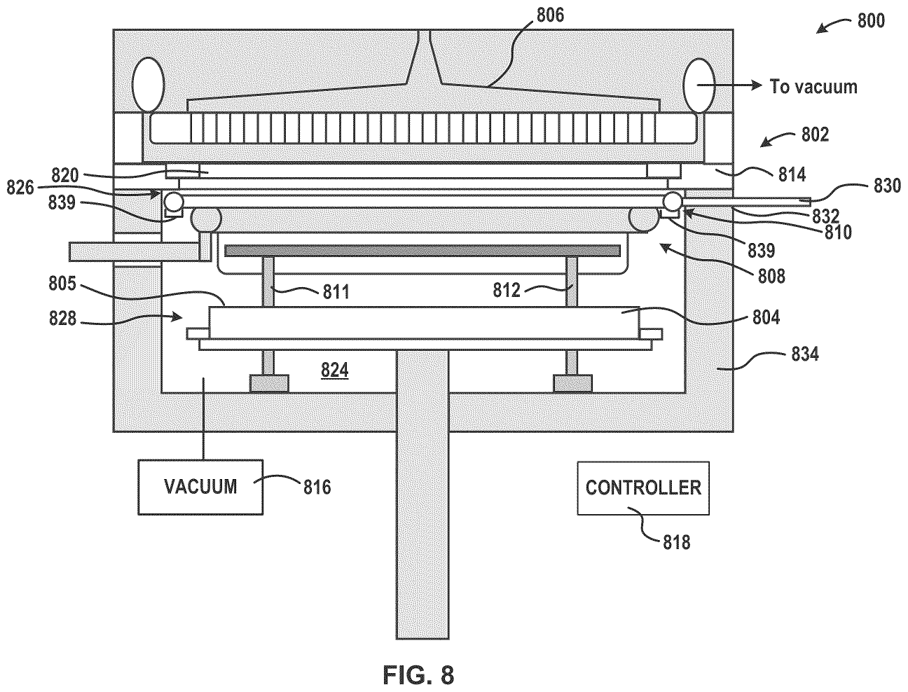

FIG. 8 illustrates yet another reactor system 800 in accordance with examples of the disclosure. Reactor system 800 includes a reactor 802, a susceptor 804, a gas distribution device 806, a temperature regulation device 808, and a separator 810. In the illustrated example, reactor system 800 can also include lift pins 811, 812, a flow control ring 814, vacuum source 816, and a controller 818. Although not illustrated, reactor system 800 may additionally include direct and/or remote plasma and/or thermal excitation apparatus for one or more reactants and/or within reactor 802.

Similar to reactors described above, reactor 802 includes an upper chamber region 820 and a lower chamber region 824. Flow control ring 814 can be used to restrict gas flow between upper chamber region 820 and lower chamber region 824 when susceptor 804 is in a first or processing position.

Susceptor 804 can be the same or similar to susceptor 104 described above. Susceptor 804 is configured to retain a substrate during processing. To this end, susceptor 804 includes a top surface 805 that can define, in part, upper chamber region 820 during substrate processing.

Gas distribution device 806, lift pins 811, 812, flow control ring 814, and vacuum source 816 can be the same or similar to lift pins, flow control rings, and vacuum sources described above.

Temperature regulation device 808 can include any temperature regulation device described herein. For example, temperature regulation device 808 can be or include a heater, such as one or more of an infrared lamp, a flash lamp, an RF plasma source, a microwave plasma source, or the like. As illustrated, temperature regulation device 808 can be disposed in the lower chamber region 824 and separate from the susceptor 804. When temperature regulation device 808 includes a plasma source, reactor system 800 can include a moveable ground plane as described above in connection with FIGS. 6 and 7. Separator 810 can provide isolation between a first portion 826 of lower chamber region 824 and a second portion 828 of lower chamber region 824. As illustrated, separator 810 can be located below flow control ring 814 and/or below upper chamber region 820 (e.g., within lower chamber region 824).

In accordance with examples of the disclosure, separator 810 includes a gas curtain between upper chamber region 820 and portions of the lower chamber region 824 and/or between portions 826 and 828 of lower chamber region 824. In these cases, separator/gas curtain 810 can include a gas inlet 830 and a conduit 832 that extends through a chamber wall 834 of reactor 802. An inert gas can be flowed through gas inlet 830 to form the gas curtain.

In accordance with additional or alternative embodiments of the disclosure, separator 810 can be or include a shutter 839 between upper chamber region 820 and portions of the lower chamber region 824 and/or between portions 826 and 828 of lower chamber region 824.

As noted above, various methods can be performed within a single reactor of a reactor system. In other cases, various steps of methods described herein can be performed within different reactors—e.g., different reactors of a process module and/or process system.

FIG. 9 illustrates an exemplary process system 900 in accordance with examples of the disclosure. Process system 900 includes a plurality of process modules 902-908, a substrate handling chamber 910, a controller 912, a load lock chamber 914, and an equipment front end module 916.

In the illustrated example, each process module 902-908 includes four reaction chambers RC1-RC4. Unless otherwise noted, RC1-RC4 can be in any suitable order. Further, process modules in accordance with examples of the disclosure can include any suitable number of reaction chambers. Further, various process modules within a process system can be configured the same or differently.

In accordance with examples of the disclosure, at least one process module comprises a first reaction chamber RC1, a second reaction chamber RC2, a third reaction chamber RC3, and optionally a fourth reaction chamber RC4. In accordance with further examples, two or more (e.g., 2, 3, or 4) of process modules 902-908 include a first reaction chamber RC1, a second reaction chamber RC2, a third reaction chamber RC3, and optionally a fourth reaction chamber RC4.

In accordance with examples of the disclosure, at least one process module 902-908 comprises a first reaction chamber RC1 that is configured as a reactor system (e.g., reactor system 100, 200, 300, 400, 600, 700, or 800) as described herein. In accordance with various examples of the disclosure, one or more of RC1-RC4 can be used to perform a deposition process (e.g., a cyclical deposition process) or step (e.g., a step of a cyclical deposition process) as described herein and another of RC1-RC4 can be used to perform another step or process or heat a substrate for a subsequent step or process.

Substrate handling chamber 910 couples to each process module 902-908. By way of example, substrate handling chamber 910 can couple to each process module 902-908 via gate valves 918-932. In accordance with examples of the disclosure, process module 902-908 can be coupled to and decoupled from substrate handling chamber 910.

Substrate handling chamber 910 can be used to move substrates between load lock chamber 914 and one or more process modules 902-908 and/or between process modules 902-908. Substrate handling chamber 910 can include a back end robot 934. Back end robot 934 can transport substrates from load lock chamber 914 (e.g., stages 940, 942 therein) and any one of the susceptors within any of the reaction chambers. Back end robot 934 can be or include, for example, a multi joint robot. By way of example, back end robot 934 can retrieve and move a substrate to be transported using electrostatic or vacuum force. Back end robot 934 can be, for example, an end effector.

Controller 912 can be configured to perform one or more steps or functions as described herein. Similar to controllers described above, controller 912 includes electronic circuitry and software to selectively operate valves, manifolds, heaters, pumps and other components included in process system 900. Such circuitry and components operate to provide gases, regulate temperature, and the like to provide proper operation of process system 900. Controller 912 can include modules, such as software and/or hardware components, which perform certain tasks. A module may be configured to reside on the addressable storage medium of the control system and be configured to execute one or more processes, such as a method described herein.

Load lock chamber 914 is connected to substrate handling chamber 910 via, for example, gate valves 936, 938 and to equipment front end module 916. Load lock chamber 914 can include one or more, e.g., two stages 940, 942 for staging substrates between equipment front end module 916 and substrate handling chamber 910.

Equipment front end module 916 is coupled to load lock chamber 914 via an opening 944. Front end module 916 can suitably include one or more load ports 946. Load ports 946 can be provided to accommodate a substrate carrier, such as a front opening unified pod (FOUP) 948. A robot 950 provided in the equipment front end module 916 can transport one or more (e.g., two at a time) substrates between FOUP 948 and the stages 940, 942 within load lock chamber 914.

FIG. 10 illustrates a top cut-away view of an exemplary process module 902 in greater detail. In the illustrated example, process module 902 includes first reaction chamber RC1, second reaction chamber RC2, third reaction chamber RC3, and fourth reaction chamber RC4. First reaction chamber RC1 and second reaction chamber RC2 can be located at a position closer to substrate handling chamber 910 than third reaction chamber RC3 and fourth reaction chamber RC4. One or more reaction chambers RC1-RC4 can be separated from each other using one or more of a gas curtain (GC) and one or more physical barriers (e.g., a shutter) having an area or opening (which may be scalable) to allow substrates therethrough. In accordance with examples of the disclosure, substrate handling chamber 910 can communicate directly or via a gate valve(s) (e.g., gate valves 918, 920) with RC1 and RC2.

In the illustrated example, process module 902 includes a transfer arm 1002 to move substrates between reaction chambers RC1-RC4 within process module 902. Transfer arm 1002 can include a first through n arm for each reaction chamber. For example, transfer arm 1002 can include a first arm 1002a, a second arm 1002b, a third arm 1002c, a fourth arm 1002d, and a shaft 1002c. First arm 1002a, second arm 1002b, third arm 1002c, and fourth arm 1002d are supported by shaft 1002e, and rotated by rotation of the shaft 1002e. Arms 1002a-1002d are located between the reaction chambers or inside a specific reaction chamber according to the rotational state of the shaft 1002e. Transfer arm 1002 can be used to provide a substrate onto a susceptor within a reaction chamber and take out a substrate on the susceptor. Transfer arm 1002 can serve as a rotation arm for moving a substrate in one of the first to fourth reaction chambers RC1-RC4 into another reaction chamber. Such a rotation arm rotates, for example, counterclockwise by degrees calculated by 360/number of reaction chambers. Process modules 904-908 may be configured to have the same or similar configuration as process module 902, illustrated in FIG. 10.

In accordance with further examples of the disclosure, as illustrated in FIG. 10, back end robot 934 can transfer substrates 1004, 1006 to/from RC1 and RC2. One or more sensors 1008-1014 can be provided in a region between substrate handling chamber 910 and the process module 902. For example, two sensors 1008, 1010 can be provided in front of first reaction chamber RC1, and two sensors 1012, 1014 can be provided in front of second reaction chamber RC2. One or more sensors 1008-1014 can include a light emitting element and a light sensing element that overlap each other (e.g., in a vertical direction). The light emitting element can emit (e.g., laser) light in a positive or negative direction, and the light sensing element detects the (e.g., laser) light. The presence or absence of a substrate between the light emitting element and the light sensing element can be detected based on reception or non-reception of light by the light receiving element. For example, the light receiving element can output a high-level signal when it senses a threshold amount of light, and output a low-level signal when it receives no or below a threshold level amount of light. The light sensing element can provide an output of a waveform corresponding to the passage condition of a substrate.

Process module 902 can also include an automatic substrate sensing unit for determining whether a substrate has passed a predetermined position when the substrate is transferred from substrate handling chamber 910 to first reaction chamber RC1 or second reaction chamber RC2 by back end robot 934. The automatic wafer sensing unit can include, for example, the aforementioned sensors 1008-1014 and a transfer module controller (TMC) 1016 connected to the sensors 1008-1014. TMC 1016 can be located, for example, under substrate handling chamber 910. TMC 1016 can compare a detection result of one or more sensors 1008-1014 with a predetermined waveform to determine whether the substrate has passed the predetermined position. In this way, it is possible to perform detection of abnormal transfer by the automatic wafer sensing unit when a substrate is transferred in a direction from substrate handling chamber 910 to first reaction chamber RC1 or second reaction chamber RC2 or when a substrate is transferred in the opposite direction. The abnormal transfer may be caused by misalignment of the substrate with respect to back end robot 934, cracking of the substrate, or the like. According to an example, it is possible for TMC 1016 to realize a correction function for correcting a transfer destination when abnormal transfer is detected. In the illustrated example reactor process module 902 can also include gas sources 1018-1030, which can include precursor gas sources, reactant gas sources, and/or inert gas sources.

Although exemplary embodiments of the present disclosure are set forth herein, it should be appreciated that the disclosure is not so limited. For example, although the assemblies, reactors systems, and methods are described in connection with various specific configurations, the disclosure is not necessarily limited to these examples. Various modifications, variations, and enhancements of the exemplary assemblies, reactors, systems, and methods set forth herein may be made without departing from the spirit and scope of the present disclosure.

The subject matter of the present disclosure includes all novel and nonobvious combinations and subcombinations of the various systems, assemblies, reactors, components, and configurations, and other features, functions, acts, and/or properties disclosed herein, as well as any and all equivalents thereof.

What is claimed is:

1. A reactor system comprising:
a reactor comprising a chamber defined, in part, by a chamber wall;
a susceptor configured to retain a substrate during processing;
a temperature regulating gas source coupled to the reaction chamber via a conduit, the temperature regulating gas source comprising a temperature regulating gas; and
a gas temperature regulating device configured to increase and/or decrease a temperature of the temperature regulating gas,
wherein the conduit is configured to provide the temperature regulating gas proximate the substrate.

2. The reactor system of claim 1, wherein the conduit comprises a section through the chamber wall.

3. The reactor system of claim 1, wherein the conduit is fluidly coupled to a portion of a gas distribution device.

4. The reactor system of claim 1, wherein the gas temperature regulating device is within the reactor.

5. The reactor system of claim 1, wherein the reactor comprises an upper chamber region and a lower chamber region, wherein the gas temperature regulating device is within the lower chamber region.

6. The reactor system of claim 1, wherein the temperature regulating gas comprises one or more of hydrogen, helium, or argon, in any combination.

7. The reactor system of claim 1, wherein the gas temperature regulating device comprises one or more of a chiller, a heat exchanger, a resistive heater, a microwave plasma device, a radiant heater, an infrared heater, a flash lamp, or a compressor.

8. A deposition method comprising the steps of:
placing a substrate on a surface of a susceptor;
heating the substrate to a first temperature using a first heater; and
using one or more lift pins, moving the substrate to a lifted position and heating the substrate in the lifted position to a second temperature different from the first position,
wherein a temperature of the substrate is modulated during the deposition method.

9. The method of claim 8, wherein the first temperature is greater than the second temperature.

10. The method of claim 8, further comprising exposing the substrate to a reactant while the substrate is on the surface of the susceptor.

11. The method of claim 8, further comprising exposing the substrate to a precursor while the substrate is in the lifted position.

12. The method of claim 11, wherein the precursor comprises a metal organic precursor.

13. The method of claim 8, wherein the first temperature is between about 300° C. and about 500° C.

14. The method of claim 8, wherein the second temperature is between about 50° C. and about 150° C.

15. A method of modulating a temperature of a substrate within a reactor, the method comprising the steps of:
placing a substrate on a surface of a susceptor;
using a first heater, heating the substrate in a first position to a first temperature; and
using an inert gas plasma source, heating the substrate in a second position to a second temperature.

16. The method of claim 15, wherein the first position and the second position are within different reaction chambers of a module.

17. The method of claim 15, wherein the first position and the second position are within a reaction chamber.

18. The method of claim 15, wherein the substrate is coupled to a first ground plane in the first position and is coupled to a second ground plane in the second position.

19. The method of claim 15, wherein the inert gas plasma source comprises a microwave plasma source.

20. The method of claim 15, comprising performing an anneal process when the substrate is in the second position.

21. A reactor system comprising:
a reactor comprising an upper chamber region and a lower chamber region;
a susceptor configured to retain a substrate during processing, the susceptor comprising a top surface defining, in part, the upper chamber region; and
a temperature regulation device disposed in the lower chamber region and separate from the susceptor.

22. The reactor system of claim 21, further comprising a gas curtain between the upper chamber region and a portion the lower chamber region.

23. The reactor system of claim 21, further comprising a shutter between the upper chamber region and the lower chamber region.
